(19) United States
(12) Patent Application Publication
(10) Pub. No.: US 2026/0191090 A1
(43) Pub. Date: Jul. 2, 2026

(54) RESIN COMPOSITION FOR MOLDING MEMBER AND METHOD OF MANUFACTURING SEMICONDUCTOR PACKAGE USING THE SAME

(71) Applicant: Samsung Electronics Co., Ltd., Suwon-si (KR)

(72) Inventor: Taehyung Lee, Suwon-si (KR)

(21) Appl. No.: 19/429,393

(22) Filed: Dec. 22, 2025

(30) Foreign Application Priority Data
Dec. 27, 2024 (KR) 10-2024-0199325

(51) Int. Cl. H10W 74/47; C08G 59/20; H10W 46/00; H10W 74/01; H10W 74/10

(52) U.S. Cl. CPC H10W 74/473; C08G 59/20; H10W 46/607; H10W 74/01; H10W 74/114

(57) ABSTRACT

A resin composition for forming a molding member included in a semiconductor package may include an epoxy resin in a range of about 2 wt % to about 10 wt %, a hardener in a range of about 2 wt % to about 10 wt %, a filler in a range of about 70 wt % to about 90 wt %, a light absorber in a range of about 0.1 wt % to about 3 wt %, and an additive in a range of about 0.1 wt % to about 3 wt %, and the light absorber includes a compound having a heptamethine cyanine structure. A method of manufacturing a semiconductor package may include forming a molding member using the resin composition.

### CROSS-REFERENCE TO RELATED APPLICATION

This application is based on and claims priority under 35 U.S.C. § 119 to Korean Patent Application No. 10-2024-0199325, filed on Dec. 27, 2024, in the Korean Intellectual Property Office, the disclosure of which is incorporated by reference herein in its entirety.

### FIELD

The inventive concept relates to a resin composition, and more specifically, to a resin composition for a molding member and a method of manufacturing a semiconductor package using the same.

### BACKGROUND

With the rapid development of the electronics industry and the demands of users, electronic devices are becoming increasingly smaller and lighter, and accordingly, the integration of semiconductor elements, which are core components of electronic devices, is required. In semiconductor packages, a molding member plays a role in protecting semiconductor chips from the external environment and physical/chemical factors. In order to implement a semiconductor package including a highly integrated semiconductor chip in a compact size, it is required that the molding materials be formed with a small thickness.

### SUMMARY

The technical problem to be achieved by the technical spirit of the inventive concept is to provide a resin composition for a molding member capable of reducing appearance defects caused by a marking process and reducing the thickness of the molding member, and a method of manufacturing a semiconductor package using the same.

According to an aspect of the inventive concept, there is provided a resin composition for forming a molding member, the resin composition including an epoxy resin in a range of about 2 weight percent (wt %) to about 10 wt %, a hardener in a range of about 2 wt % to about 10 wt %, a filler in a range of about 70 wt % to about 90 wt %, a light absorber in a range of about 0.1 wt % to about 3 wt %, and an additive in a range of about 0.1 wt % to about 3 wt %, wherein the light absorber comprises a compound having a heptamethine cyanine structure.

According to an aspect of the inventive concept, there is provided a method of manufacturing a semiconductor package, the method including mounting a semiconductor chip on a package substrate, forming a molding member using a resin composition surrounding the semiconductor chip on the package substrate, wherein the resin composition includes an epoxy resin in a range of about 2 wt % to about 10 wt %, a hardener in a range of about 2 wt % to about 10 wt %, a filler in a range of about 70 wt % to about 90 wt %, a light absorber in a range of about 0.1 wt % to about 3 wt %, and an additive in a range of about 0.1 wt % to about 3 wt %, wherein the light absorber comprises a compound having a heptamethine cyanine structure, and marking a pattern on an upper surface of the molding member by laser irradiation.

According to an aspect of the inventive concept, there is provided a method of manufacturing a semiconductor package, the method including mounting a semiconductor chip on a package substrate, forming a molding member using a resin composition surrounding the semiconductor chip on the package substrate, wherein the resin composition comprises an epoxy resin in a range of about 2 wt % to about 10 wt %, a hardener in a range of about 2 wt % to about 10 wt %, a filler in a range of about 70 wt % to about 90 wt %, a light absorber in a range of about 0.1 wt % to about 3 wt %, and an additive in a range of about 0.1 wt % to about 3 wt %, and marking a pattern on an upper surface of the molding member by laser irradiation, wherein the light absorber includes a compound having at least one structure among Formula 1, Formula 2, Formula 3, and Formula 4:

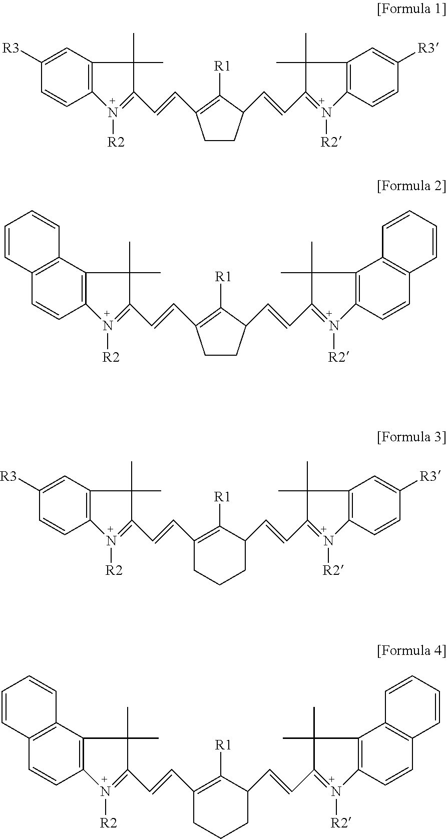

wherein R1 is a barbiturate group, R2 and R2′ independently are a methyl group, an ethyl group, or a 3-methylbutyl group, and R3 and R3′ independently are hydrogen or chlorine.

### BRIEF DESCRIPTION OF THE DRAWINGS

Embodiments will be more clearly understood from the following detailed description taken in conjunction with the accompanying drawings in which:

FIG. 1 is a cross-sectional view showing a semiconductor package according to embodiments;

FIG. 2 is an enlarged view of part A of FIG. 1;

FIG. 3 is a cross-sectional view showing a semiconductor package according to embodiments;

FIG. 4 is a flowchart showing a method of manufacturing a semiconductor package, according to embodiments; and

FIGS. 5 to 7 are cross-sectional views showing a method of manufacturing a semiconductor package, according to embodiments.

### DETAILED DESCRIPTION OF THE EMBODIMENTS

Hereinafter, embodiments of the technical idea of the inventive concept will be described in detail with reference to the accompanying drawings.

Example embodiments relate to a resin composition for a molding member included in a semiconductor package. The resin composition according to some embodiments may be used in a method of manufacturing a semiconductor package, and a cured product of the resin composition may include a molding member included in the semiconductor package.

The resin composition according to some embodiments may include an epoxy resin, a hardener, a filler, an additive, and a light absorber.

Table 1 shows the contents of the epoxy resin, the hardener, the filler, the additive, and the light absorber included in the resin composition according to example embodiments in units of weight percent.

TABLE 1

| Composition | Content (wt %) |
|---|---|
| Epoxy resin | 2 to 10 |
| hardener | 2 to 10 |
| Filler | 70 to 90 |
| Additive | 0.1 to 3 |
| Light absorber | 0.1 to 3 |

In example embodiments, the epoxy resin may be included in the resin composition in a range from about 2 wt % to about 10 wt %, or any range therein, for example, about 2 wt % to about 5 wt %, about 5 wt % to about 10 wt %, or about 3 wt % to about 7 wt %. In example embodiments, the hardener may be included in the resin composition in a range from about 2 wt % to about 10 wt %, or any range therein, for example, about 2 wt % to about 5 wt %, about 5 wt % to about 10 wt %, or about 3 wt % to about 7 wt %. In example embodiments, the filler may be included in the resin composition in a range from about 70 wt % to about 90 wt %, or any range therein, for example, about 70 wt % to about 80 wt %, about 80 wt % to about 90 wt %, or about 75 wt % to about 85 wt %.

In example embodiments, the additive may be included in the resin composition in a range from about 0.1 wt % to about 3 wt %, or any range therein, for example, about 0.1 wt % to about 1.5 wt %, about 1.5 wt % to about 3 wt %, or about 0.5 wt % to about 2 wt %. In example embodiments, the light absorber may be included in the resin composition in a range from about 0.1 wt % to about 3 wt %, or any range therein, for example, about 0.1 wt % to about 1.5 wt %, about 1.5 wt % to about 3 wt %, or about 0.5 wt % to about 2 wt %.

In example embodiments, the epoxy resin may be a matrix or binder of a molding member formed by hardening the resin composition. In example embodiments, the epoxy resin may include at least one of a bisphenol-A type epoxy, a bisphenol-F type epoxy, a rubber modified epoxy, a novolac epoxy, a cycloaliphatic epoxy, a tetra-functional epoxy, an acrylic modified epoxy, a coal tar modified epoxy, an aliphatic chain modified epoxy, a cresol novolac epoxy, a polyglycol epoxy, a cardanol epoxy, a brominated epoxy, and/or a phenoxy epoxy.

In example embodiments, the hardener may react with the epoxy resin in the resin composition to cause a hardening reaction of the epoxy resin. In example embodiments, the hardener may include at least one of an acid anhydride hardener, a cationic hardener, an imidazole hardener, a dicyandiamide hardener, and an amine adduct type hardener.

In example embodiments, the acid anhydride hardener may include at least one of dodecenyl succinic anhydride (DDSA), polyadipic acid (PADA), polysebacic acid (PSPA), methyl tetrahydrophthalic anhydride (Me-THPA), methyl hexahydrophthalic anhydride (Me-HHPA), methylhymic anhydride (MHAC), tetrahydrophthalic anhydride (THPA), phthalic anhydride (PA), trimethylicanhydride (TMA), pyromethylic anhydride (PMDA), benzophenon tetracarboxylic anhydride (BTDA), chlorendic anhydride, and tetrabromo phthalic anhydride (TBPA).

In example embodiments, the cationic hardener may include at least one of [4-acetyloxy)phenyl]dimethylsulfonium(OC-6-11)-hexafluoroantimonate(1-), PC-2508, CXC-1742, CXC-1751, N-benzylpyrazinium hexafluoroantimonate (BPH), XNA-2201, and XNA-2202.

In example embodiments, the imidazole hardener may include one or more of 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazineisocyanuric acid adduct, 2-phenylimidazoleisocyanuric acid adduct, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, 2-phenylimidazoline, etc.

In example embodiments, the filler may be dispersed within the molding member to form a heat dissipation path and may reduce a coefficient of thermal expansion of the molding member and improve thermal conductivity. The filler may include an inorganic material-based filler having excellent heat dissipation properties. In example embodiments, the filler may include at least one of silica, alumina, magnesium oxide, aluminum nitride, and boron nitride.

In example embodiments, the filler may be contained in the resin composition in a particle or powder state, and after the resin composition is cured and converted into the molding member, the filler may be evenly dispersed and disposed within the molding member. The filler particles included within the resin composition may be maintained without being volatilized or deformed within the molding member.

In example embodiments, the filler included within the resin composition may have a particle size in a range from about 0.1 micrometer (μm) to about 100 μm. In example embodiments, the filler may have an average particle size in a range from about 1 μm to 50 μm.

In example embodiments, the additive may include pigments, dyes, leveling agents, dispersants, adhesion promoters, coupling agents, softeners, etc. In example embodiments, the additive may be added to control reaction rates, improve stability, control colors, etc. In example embodiments, the additive may be included in the resin composition in a range from about 0.1 wt % to about 3 wt %. In other words, the additive may be optionally included in the resin composition, and in example embodiments, the additive may not be included in the resin composition.

In example embodiments, the light absorber may include a material capable of absorbing light having a wavelength in a range of about 700 nanometers (nm) to about 1,200 nm, or any range therein. In example embodiments, the light absorber may include a compound having a heptamethine cyanine structure. In example embodiments, the light absorber may include a compound having a heptamethine cyanine structure at least at one of R1, R2, R2′, R3, and R3′, and including a cyclopentene or cyclohexene structure.

In example embodiments, the light absorber may be represented by at least one structure of [Formula 1], [Formula 2], [Formula 3], and [Formula 4], but is not limited thereto. R1 may comprise a barbiturate group having a structure of [Formula 5], [Formula 6], or [Formula 7], R2 and R2′ may include a methyl group, an ethyl group, or a 3-methylbutyl group (e.g., CH₂CH₂CH(CH₃)₂), and R3 and R3′ may include hydrogen, chlorine, or the like, but are not limited thereto.

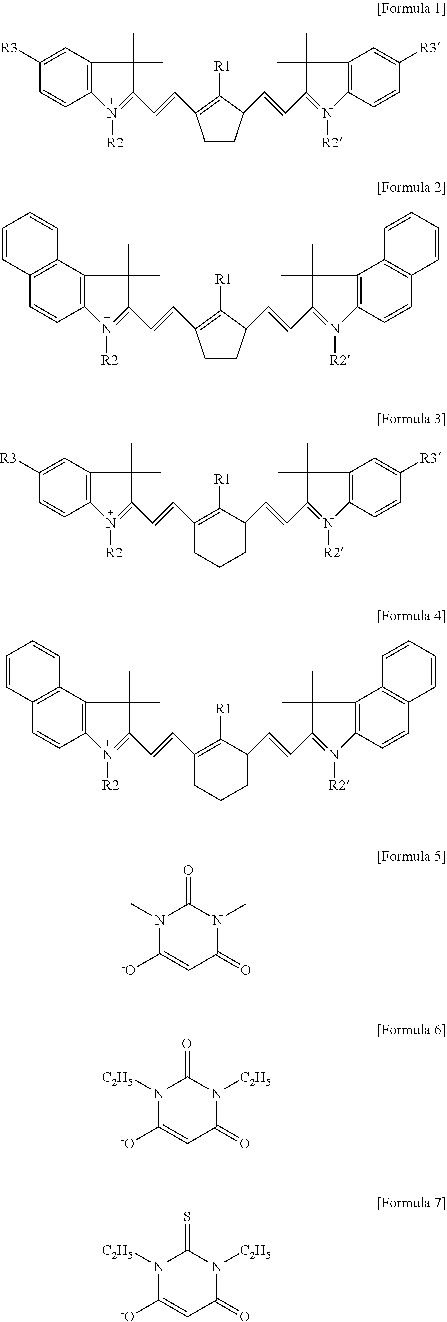

In the resin composition according to embodiments, the light absorber may be included in an amount range from about 0.1 wt % to about 3 wt %, or any range therein, and may have a high absorption rate for light in a wavelength range of about 700 nm to about 1,200 nm, or any range therein, for example, light used in a laser marking process. In example embodiments, as the resin composition includes the light absorber, when forming a molding member using the resin composition and then performing a laser marking process, a marking depth may be reduced due to the increased light absorption rate, and/or a relatively shallow depth of marking may be formed, and thus, a thickness of the molding member between the semiconductor chip and the marking portion may be maintained sufficiently large. Therefore, a semiconductor package formed by using the resin composition may have reduced and/or prevented appearance defects and may have excellent reliability.

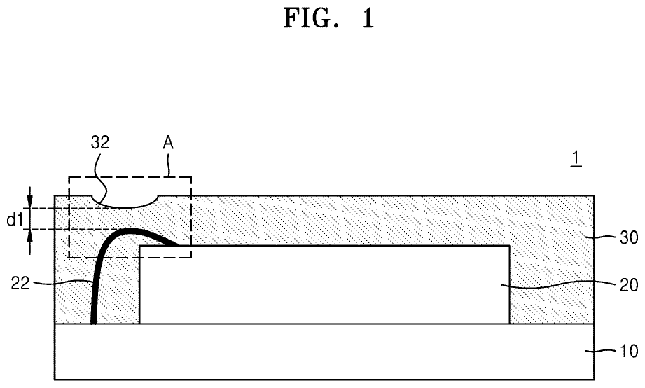

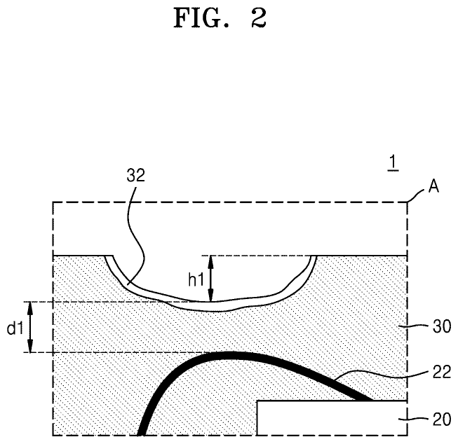

FIG. 1 is a cross-sectional view showing a semiconductor package 1 according to embodiments, and FIG. 2 is an enlarged view of part A of FIG. 1.

The semiconductor package 1 illustrated in FIGS. 1 and 2 may be a semiconductor package formed using a resin composition according to embodiments.

Referring to FIGS. 1 and 2, the semiconductor package 1 may include a package substrate 10, a semiconductor chip 20, and a molding member 30. In example embodiments, the molding member 30 may be arranged to surround an upper surface and side surfaces of the semiconductor chip 20 on the package substrate 10. The molding member 30 may be a hardened product of the resin composition according to embodiments. The semiconductor package 1 may include a marking pattern 32 formed on an upper surface of the molding member 30.

In example embodiments, the package substrate 10 may include a printed circuit board or an interposer. In example embodiments, the package substrate 10 may be a carrier substrate. Alternatively, in example embodiments, a redistribution structure including a stacked structure of a redistribution insulating layer and a redistribution layer may be placed instead of the package substrate 10.

In example embodiments, the semiconductor chip 20 may be mounted on the package substrate 10. The semiconductor chip 20 may include a logic chip such as a central processing unit (CPU), a graphics processing unit (GPU), a field programmable gate array (FPGA), an application processor (AP), a digital signal processor, an encryption processor, a microprocessor, a microcontroller, an analog-to-digital converter, an application-specific IC (ASIC), and/or a memory chip including a volatile memory such as dynamic RAM (DRAM), static RAM (SRAM), and/or a nonvolatile memory such as phase change RAM (PRAM), magnetic RAM (MRAM), resistive RAM (RRAM), and a flash memory.

In example embodiments, a plurality of semiconductor chips 20 may be mounted on the package substrate 10 in a horizontal direction and/or may be stacked in a vertical direction.

In example embodiments, the semiconductor chip 20 may be electrically connected to the package substrate 10 by a bonding wire 22. In example embodiments, the plurality of semiconductor chips 20 may be stacked in a vertical direction, and two adjacently arranged semiconductor chips 20 may be electrically connected to each other by the bonding wire 22, and the uppermost semiconductor chip 20 or the lowermost semiconductor chip 20 may be electrically connected to the package substrate 10 by the bonding wire 22. In example embodiments, the bonding wire 22 may have a portion that is arranged at a vertical level higher than the upper surface of the semiconductor chip 20.

In other embodiments, instead of providing the bonding wire 22, the semiconductor chip 20 may be electrically connected to the package substrate 10 by a connecting terminal such as a pad, a connecting bump, or a solder, or each of the plurality of semiconductor chips 20 may be electrically connected to each other.

In example embodiments, the molding member 30 may be formed using the resin composition according to the embodiments described above, and for example, the molding member 30 may be an epoxy resin-based molding member formed by hardening a resin composition including an epoxy resin, a hardening agent, a filler, an additive, and a light absorber. The filler may be dispersed and distributed within the molding member 30.

In example embodiments, the light absorber included within the molding member 30 may include a compound having a heptamethine cyanine structure. In example embodiments, the light absorber may include a compound having a heptamethine cyanine structure including at least one functional group among R1, R2, R2′, R3, and R3′, and including a cyclopentene or cyclohexene structure.

In example embodiments, the light absorber may be represented by at least one structure of [Formula 1], [Formula 2], [Formula 3], and [Formula 4], but is not limited thereto. R1 may comprise a barbiturate group having a structure of [Formula 5], [Formula 6], or [Formula 7], R2 and R2′ may include a methyl group, an ethyl group, or a 3-methylbutyl group (e.g., CH₂CH₂CH(CH₃)₂), and R3 and R3′ may include hydrogen, chlorine, or the like, but are not limited thereto.

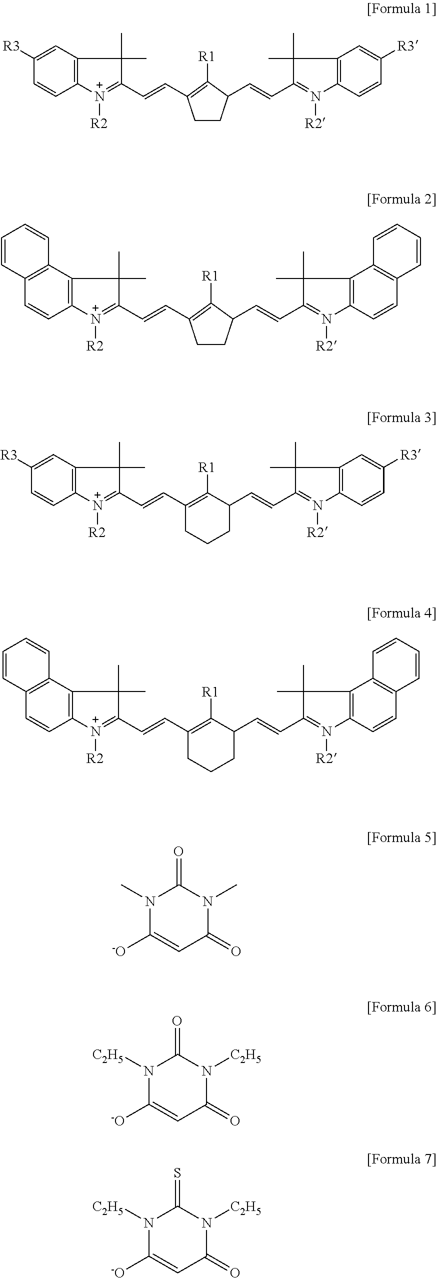

In example embodiments, the semiconductor package 1 may include a marking pattern 32 formed on the upper surface of the molding member 30. The marking pattern 32 may be composed of various types of pictures, symbols, numbers, codes, or characters that include information about the semiconductor chip 20.

In example embodiments, the marking pattern 32 may indicate a recessed area that is sunken by a predetermined depth hi from the upper surface of the molding member 30. Alternatively, in example embodiments, the marking pattern 32 may be a region in which a material constituting the molding member 30 is burned, which is formed in a recessed region that is sunken by a predetermined depth from the upper surface of the molding member 30.

In example embodiments, the marking pattern 32 may be formed by irradiating the molding member 30 with laser light through a laser marking process. In example embodiments, because the light absorber is included in the molding member 30, the molding member 30 may have improved light absorption for laser light, and the marking depth (e.g., the recess depth hi of the marking pattern 32) may be reduced in the laser marking process for forming the marking pattern 32 relative to a molding member that does not contain the light absorber.

As illustrated in FIGS. 1 and 2, when at least a portion of the bonding wire 22 is arranged at a vertical level higher than the upper surface of the semiconductor chip 20, a vertical distance d1 from the uppermost portion of the bonding wire 22 to the marking pattern 32 (or the lowest surface of the recess area of the marking pattern 32) may be maintained relatively large. Therefore, the semiconductor package 1 may have reduced and/or prevented appearance defects and may have excellent reliability.

In general, the molding material may include a black pigment as an additive and thus, a structure inside the semiconductor package is not visible from the outside. However, in the laser marking process, the temperature of a portion to which laser light is irradiated locally experiences a temperature increase, and the pigment is oxidized and discolored in the region where the temperature increases, or a resin material is thermally decomposed, exposing the filler to a surface of the molding member, and thus changes to a bright color. That is, a recessed marking pattern is formed as a result of the laser irradiation, and the color of the marking pattern may change. However, as the thickness of the package gradually decreases to form a compact package, if the depth of the marking pattern is deep, appearance defects, in which the bonding wires or the shape of the semiconductor chip inside the semiconductor package are visible to the eyes, may occur. Also, crack resistance of the semiconductor package is reduced because the molding member under the marking pattern is relatively thin.

In the semiconductor package 1 according to embodiments, the molding member 30 includes a light absorber and converts light energy irradiated in a laser process into heat energy, and thus, the marking pattern 32 may be efficiently formed even using the irradiation of small energy of laser light. In addition, when irradiating with the same energy of laser, the penetration depth of the laser may be reduced due to the light absorption rate of the molding member 30 including a light absorber. In other words, a marking pattern 32 with a relatively shallow depth may be formed, and accordingly, the appearance defect of the semiconductor package 1 may be reduced and/or prevented, and the crack resistance of the semiconductor package 1 may be improved.

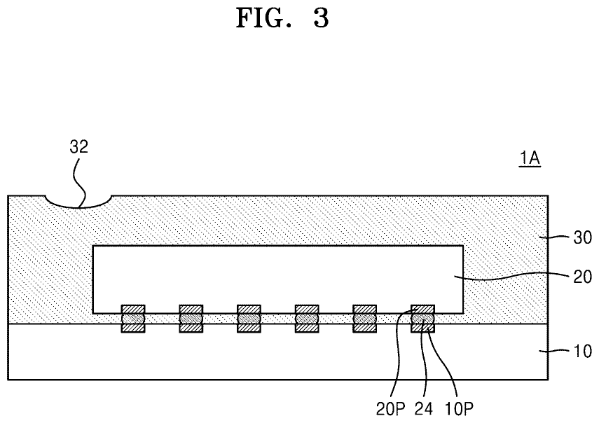

FIG. 3 is a cross-sectional view showing a semiconductor package 1A according to embodiments.

Referring to FIG. 3, a semiconductor chip 20 may be mounted on a package substrate 10 in a flip-chip manner. In example embodiments, a top pad 10P is provided on a top surface of the package substrate 10, a bottom pad 20P is provided on a bottom surface of the semiconductor chip 20, and the top pad 10P and the bottom pad 20P may be electrically connected to each other by a connection terminal 24. In example embodiments, the connection terminal 24 may include a connection bump, solder, or conductive pad.

In FIG. 3, a single semiconductor chip 20 is shown mounted on the package substrate 10 in a flip-chip manner, but in example embodiments, a semiconductor chip stack including a plurality of semiconductor chips may be mounted on the package substrate 10. The semiconductor chip stack may include a memory device that constitutes a high bandwidth memory (HBM) device, and the semiconductor chip stack may include two to several dozen semiconductor chips that are stacked vertically and electrically connected to each other. The semiconductor chip stack may include semiconductor chip stacks of various shapes and structures in addition to the HBM device described above.

A molding member 30 may be arranged to cover an upper surface and side surfaces of the semiconductor chip 20 on the package substrate 10. A marking pattern 32 may be provided on an upper side of the molding member 30.

According to some embodiments, even if the molding member 30 is formed with a thin thickness, the marking pattern 32 having a relatively shallow depth may be formed, and thus, occurrence of an appearance defect of the semiconductor package 1A may be reduced and/or prevented.

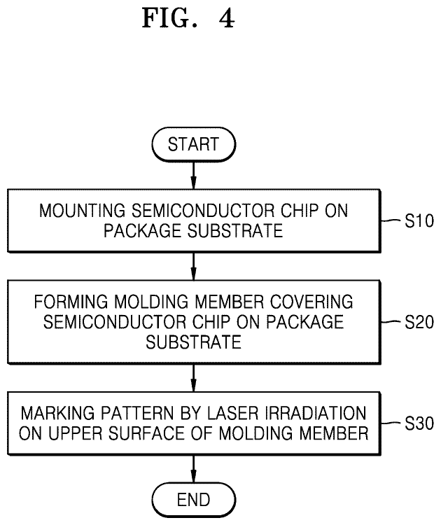

FIG. 4 is a flowchart showing a method of manufacturing a semiconductor package, according to some embodiments.

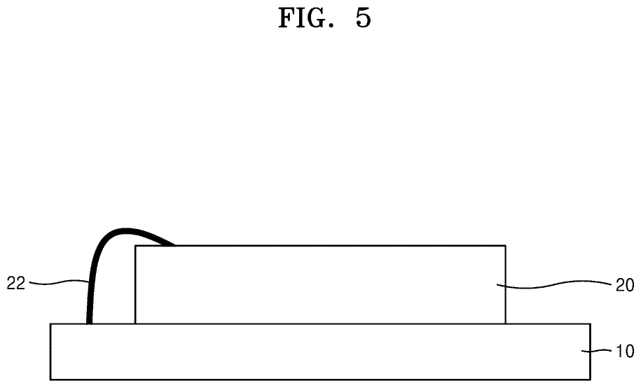

FIGS. 5 to 7 are cross-sectional views showing a method of manufacturing a semiconductor package, according to some embodiments.

Referring to FIG. 4, the method of manufacturing a semiconductor package may include a step S10 of mounting a semiconductor chip on a package substrate, a step S20 of forming a molding member covering the semiconductor chip on the package substrate, and a step S30 of forming a marking pattern on an upper surface of the molding member by laser irradiation.

Referring to FIG. 5 together with FIG. 4, a semiconductor chip 20 may be mounted on a package substrate 10.

In example embodiments, in step S10, of mounting a semiconductor chip on the package substrate 10, the semiconductor chip 20 may be composed of one or more semiconductor chips. For example, a plurality of semiconductor chips 20 may be mounted horizontally on the package substrate 10, and/or a plurality of semiconductor chips 20 may be mounted vertically on the package substrate 10.

As illustrated in FIG. 5 as an example, the semiconductor chip 20 may be electrically connected to a connection terminal provided on or inside the package substrate 10 by a bonding wire 22. In example embodiments, unlike the illustration in FIG. 5, instead of the wire bonding method, the semiconductor chip 20 may be electrically connected to the package substrate 10 by, for example, a flip chip method, for example, a connection terminal such as a pad, a connection bump, or a solder.

In example embodiments, the package substrate 10 may include an interposer or a printed circuit board. In example embodiments, the semiconductor chip 20 may be mounted on a carrier substrate instead of the package substrate 10. In example embodiments, the semiconductor chip 20 may be mounted on a redistribution structure instead of the package substrate 10.

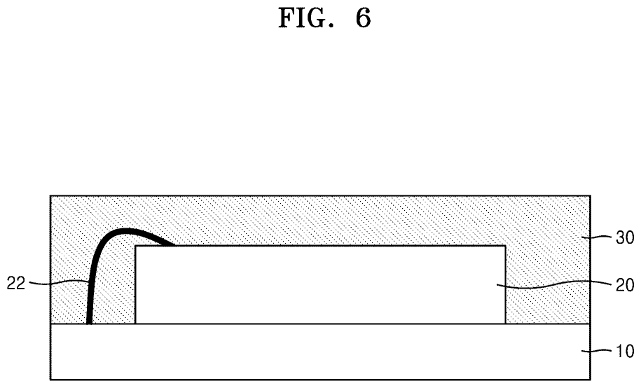

Referring to FIG. 6 together with FIG. 4, a molding member 30 covering the semiconductor chip 20 may be formed on the package substrate 10.

In example embodiments, in step S20, of forming the molding member 30 covering the semiconductor chip 20 on the package substrate 10, the molding member 30 may be formed using a resin composition according to some embodiments.

In example embodiments, the process of forming the molding member 30 using the resin composition may be a transfer molding method. The molding member 30 may be formed by placing the package substrate 10 and the semiconductor chip 20 within a cavity of a transfer mold and injecting and hardening a resin composition according to embodiments into the transfer mold. In order to inject the resin composition into the cavity of the transfer mold, the resin composition may be formed into a tablet or pellet shape.

In example embodiments, the process of forming the molding member 30 using the resin composition may be a compression molding method. The resin composition in the form of granules or powder may be injected into the cavity of the mold die, and the resin composition may be changed into a gel state. Thereafter, the package substrate 10 and the semiconductor chip 20 may be tightly pressed into the cavity and hardened to form the molding member 30.

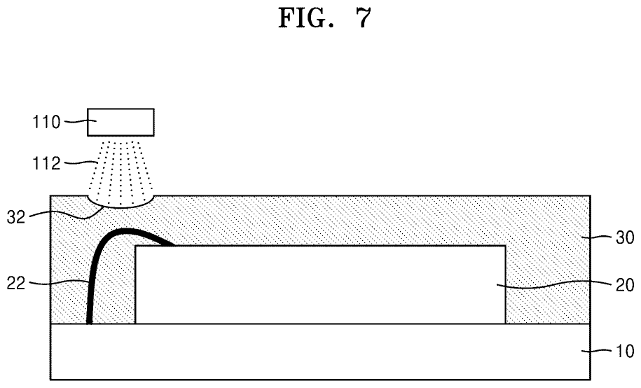

Referring to FIG. 7 together with FIG. 4, a marking pattern 32 may be formed on an upper surface of the molding member 30 by laser irradiation.

In example embodiments, the laser irradiation process may be performed so that laser light 112 may be irradiated on the upper surface of the molding member 30. The laser light 112 may be irradiated by a light source 110. In a region where the laser light 112 is irradiated, the light absorption rate may increase due to the light absorber included in the molding member 30, and the temperature of the region where the laser light 112 is irradiated may locally rise, causing combustion or thermal decomposition of the region where the laser light 112 is irradiated, and a marking pattern 32 may be formed.

The semiconductor package 1 can be completed by performing the above-described process.

According to the method of manufacturing a semiconductor package according to exemplary embodiments, the molding member 30 includes a light absorber and converts light energy irradiated in the laser process into heat energy so that the marking pattern 32 may be efficiently formed even with small energy of laser light irradiation. In addition, when irradiating the same energy of laser, the penetration depth of the laser can be reduced due to the light absorption rate of the molding member 30 including the light absorber. That is, the marking pattern 32 having a relatively shallow depth may be formed, and thus, the appearance defect of the semiconductor package 1 may be reduced and/or prevented. In addition, even if the molding member 30 is formed with a small thickness in accordance with the trend of package miniaturization, the crack resistance of the semiconductor package 1 may be improved, and thus, the reliability of the semiconductor package 1 may be improved.

According to the technical idea of the inventive concept, the resin composition for the molding member may include a light absorber in a range from about 0.1 wt % to about 3 wt %, or any range therein, and the light absorber may be a compound having a heptamethine cyanine structure and may absorb light in a range of about 700 nm to about 1,200 nm, or any range therein, for example, about 700 nm to about 1000 nm, about 900 nm to about 1200 nm, or about 800 nm to about 1100 nm. The molding member formed using the resin composition may have high light absorption in a laser marking process, and the appearance defect due to the marking process may be reduced. In addition, even if the molding member is formed with a small thickness, the crack resistance of the semiconductor package may be improved, and thus, the reliability of the semiconductor package can be improved.

While the inventive concept has been particularly shown and described with reference to embodiments thereof, it will be understood that various changes in form and details may be made therein without departing from the spirit and scope of the following claims.

What is claimed is:

1. A resin composition for forming a molding member included in a semiconductor package, the resin composition comprising:
an epoxy resin in a range of 2 weight percent (wt %) to 10 wt %;
a hardener in a range of 2 wt % to 10 wt %;
a filler in a range of 70 wt % to 90 wt %;
a light absorber in a range of 0.1 wt % to 3 wt %; and
an additive in a range of 0.1 wt % to 3 wt %,
wherein the light absorber comprises a compound having a heptamethine cyanine structure.

2. The resin composition of claim 1, wherein the light absorber is configured to absorb light having a wavelength in a range of 700 nanometers (nm) to 1,200 nm and convert the light into heat energy.

3. The resin composition of claim 1, wherein
the light absorber comprises a compound having at least one structure selected from Formula 1, Formula 2, Formula 3, and Formula 4: 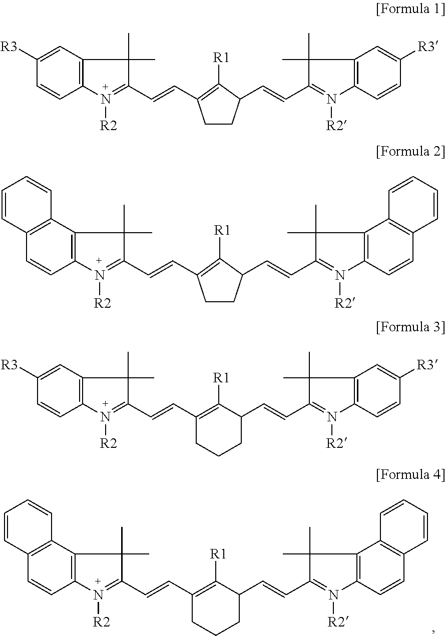
wherein R1 comprises a barbiturate group,
R2 and R2′ independently are a methyl group, an ethyl group, or a 3-methylbutyl group, and
R3 and R3′ independently are hydrogen or chlorine).

4. The resin composition of claim 3, wherein
R1 has at least one structure selected from Formula 5, Formula 6, and Formula 7.

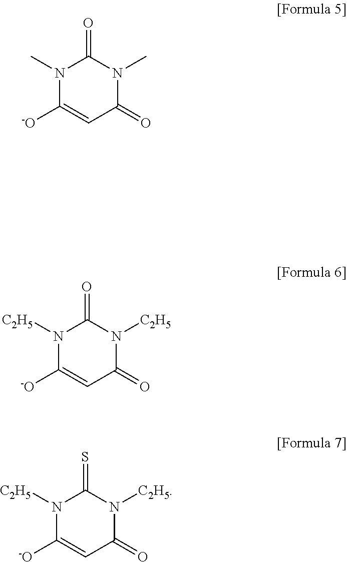

5. The resin composition of claim 1, wherein
the epoxy resin comprises at least one of a bisphenol-A type epoxy, a bisphenol-F type epoxy, a rubber modified epoxy, a novolac epoxy, a cycloaliphatic epoxy, a tetra-functional epoxy, an acrylic modified epoxy, a coal tar modified epoxy, an aliphatic chain modified epoxy, a cresol novolac epoxy, a polyglycol epoxy, a cardanol epoxy, a brominated epoxy, and a phenoxy epoxy.

6. The resin composition of claim 1, wherein
the hardener comprises at least one of an acid anhydride hardener, a cationic hardener, an imidazole hardener, a dicyandiamide hardener, and an amine adduct type hardener.

7. The resin composition of claim 1, wherein the filler comprises at least one of silica, alumina, magnesium oxide, aluminum nitride, and boron nitride.

8. The resin composition of claim 1, wherein the filler has a particle size in a range from 0.1 micrometer (μm) to 100 μm.

9. A method of manufacturing a semiconductor package, the method comprising:
mounting a semiconductor chip on a package substrate; and
forming a molding member using a resin composition surrounding the semiconductor chip on the package substrate, wherein the resin composition comprises:
an epoxy resin in a range of 2 wt % to 10 wt %;
a hardener in a range of 2 wt % to 10 wt %;
a filler in a range of 70 wt % to 90 wt %;
a light absorber in a range of 0.1 wt % to 3 wt %; and
an additive in a range of 0.1 wt % to 3 wt %, and
wherein the light absorber comprises a compound having a heptamethine cyanine structure, and
marking a pattern on an upper surface of the molding member by laser irradiation.

10. The method of claim 9, wherein marking the pattern comprises laser irradiation having a wavelength in a range of 700 nm to 1,200 nm.

11. The method of claim 9, wherein
the light absorber includes a compound having at least one structure selected from Formula 1, Formula 2, Formula 3, and Formula 4: 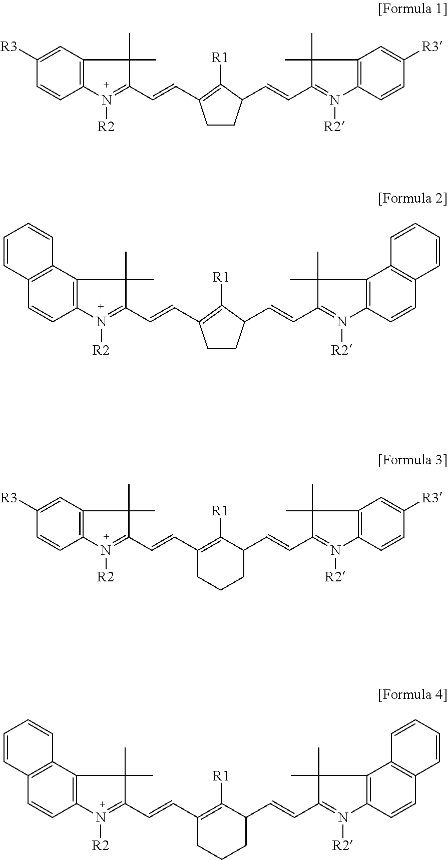
wherein R1 comprises a barbiturate group,
R2 and R2′ independently are a methyl group, an ethyl group, and a 3-methylbutyl group, and
R3 and R3′ independently are hydrogen or chlorine.

12. The method of claim 9, wherein
R1 has at least one structure selected from Formula 5, Formula 6, and Formula 7:

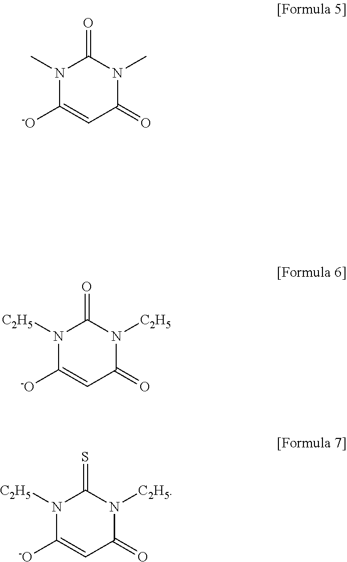

13. The method of claim 9, wherein
the epoxy resin comprises at least one of a bisphenol-A type epoxy, a bisphenol-F type epoxy, a rubber modified epoxy, a novolac epoxy, a cycloaliphatic epoxy, a tetra-functional epoxy, an acrylic modified epoxy, a coal tar modified epoxy, an aliphatic chain modified epoxy, a cresol novolac epoxy, a polyglycol epoxy, a cardanol epoxy, a brominated epoxy, and a phenoxy epoxy.

14. The method of claim 9, wherein the hardener comprises at least one of an acid anhydride hardener, a cationic hardener, an imidazole hardener, a dicyandiamide hardener, and an amine adduct type hardener.

15. The method of claim 9, wherein the filler comprises at least one of silica, alumina, magnesium oxide, aluminum nitride, and boron nitride.

16. The method of claim 9, wherein the filler has a particle size in a range from 0.1 μm to 100 μm.

17. A method of manufacturing a semiconductor package, the method comprising:
mounting a semiconductor chip on a package substrate;
forming a molding member using a resin composition surrounding the semiconductor chip on the package substrate, wherein the resin composition comprises:
an epoxy resin in a range of 2 wt % to 10 wt %;
a hardener in a range of 2 wt % to 10 wt %;
a filler in a range of 70 wt % to 90 wt %;
a light absorber in a range of 0.1 wt % to 3 wt %; and
an additive in a range of 0.1 wt % to 3 wt %, and
marking a pattern on an upper surface of the molding member by laser irradiation,
wherein the light absorber comprises a compound having at least one structure selected from Formula 1 Formula 2 Formula 3 and Formula 4: 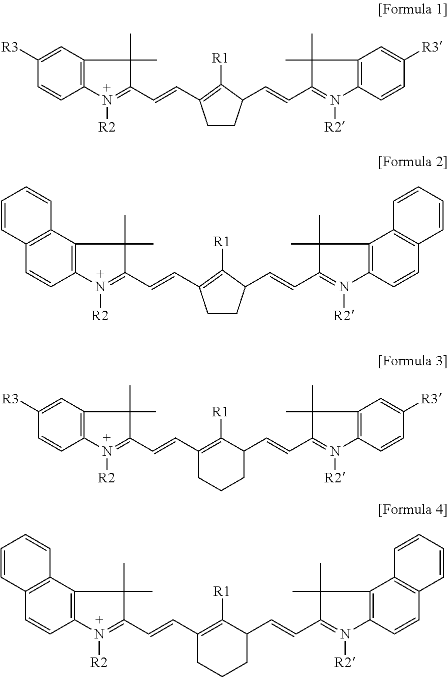
wherein R1 comprises a barbiturate group,
R2 and R2′ independently are a methyl group, an ethyl group, and a 3-methylbutyl group, and
R3 and R3′ independently are hydrogen or chlorine.

18. The method of claim 17, wherein
R1 has at least one structure selected from Formula 5, Formula 6, and Formula 7:

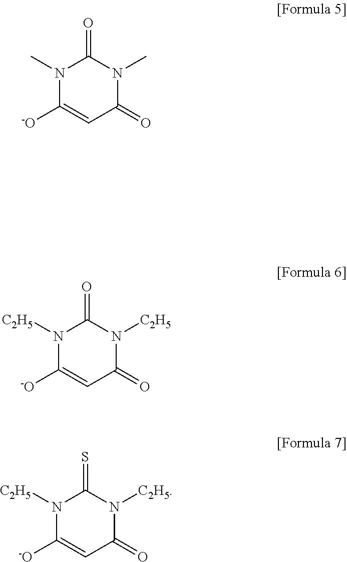

19. The method of claim 17, wherein marking the pattern comprises laser irradiation having a wavelength in a range of 700 nm to 1,200 nm.

20. The method of claim 17, wherein
the filler comprises at least one of silica, alumina, magnesium oxide, aluminum nitride, and boron nitride, and
the filler has a particle size in a range of 0.1 wt % to 100 wt %.
